(19) United States
(12) Patent Application Publication
(10) Pub. No.: US 2026/0082569 A1
(43) Pub. Date: Mar. 19, 2026

(54) SEMICONDUCTOR DEVICE

(71) Applicant: Kioxia Corporation, Tokyo (JP)

(72) Inventors: Mamoru WATANABE, Yokkaichi (JP); Mitsuhiko NODA, Kuwana (JP); Susumu HASHIMOTO, Yokkaichi (JP); Takashi IZUMIDA, Kamakura (JP); Keisuke NAKATSUKA, Kuwana (JP); Junya SAKANO, Yokohama (JP); Takeshi SHIMANE, Matsudo (JP); Taishi HAGA, Yokohama (JP)

(73) Assignee: Kioxia Corporation, Tokyo (JP)

(21) Appl. No.: 19/058,092

(22) Filed: Feb. 20, 2025

(30) Foreign Application Priority Data
Sep. 13, 2024 (JP) 2024-159163

(51) Int. Cl. H10B 43/35; H10B 43/20

(52) U.S. Cl. CPC H10B 43/35; H10B 43/20

(57) ABSTRACT

A first insulator is located in a first direction from the first substrate. A first conductor is in the first insulator. A second substrate is located more in the first direction than the first insulator. A first well region has a first conductivity type, is provided in the second substrate, and has a first impurity concentration. A first impurity region has the first conductivity type, is in contact with the first well region in the second substrate at a position located more in the second direction than the first well region, and has a second impurity concentration that is 4 times to 1×10⁸ times the first impurity concentration. A second well region has a second conductivity type and is in contact with the first impurity region in the second substrate at a position located more in the second direction than the first impurity region.

### CROSS-REFERENCE TO RELATED APPLICATIONS

This application is based upon and claims the benefit of priority from Japanese Patent Application No. 2024-159163, filed Sep. 13, 2024, the entire contents of which are incorporated herein by reference.

### FIELD

Embodiments relate generally to a semiconductor device.

### BACKGROUND

A semiconductor device includes a memory device as one of its types. Examples of the memory device include a memory device with memory cells arranged in three dimensions. To enhance the storage capacity of the storage device, the components of the memory device are becoming increasingly miniaturized.

### BRIEF DESCRIPTION OF THE DRAWINGS

FIG. 1 illustrates an example of components of a semiconductor device according to a first embodiment and how they are coupled.

FIG. 2 illustrates components of a single block of the semiconductor device according to the first embodiment and how they are coupled.

FIG. 3 illustrates an exterior of the semiconductor device of the first embodiment.

FIG. 4 illustrates an example of a structure of some planes of the semiconductor device of the first embodiment.

FIG. 5 illustrates an example of a partial sectional structure of the semiconductor device of the first embodiment.

FIG. 6 illustrates an example of a section of a memory pillar of the semiconductor device of the first embodiment along an xy plane.

FIG. 7 illustrates a structure of a portion of the semiconductor device of the first embodiment.

FIG. 8 illustrates an example of a state during the manufacturing process of a portion of the semiconductor device of the first embodiment according to the first example.

FIG. 9 illustrates an example of a state during the manufacturing process of a portion of the semiconductor device of the first embodiment according to the first example.

FIG. 10 illustrates an example of a state during the manufacturing process of a portion of the semiconductor device of the first embodiment according to the first example.

FIG. 11 illustrates an example of a state during the manufacturing process of a portion of the semiconductor device of the first embodiment according to the first example.

FIG. 12 illustrates an example of a state during the manufacturing process of a portion of the semiconductor device of the first embodiment according to the first example.

FIG. 13 illustrates an example of a state during the manufacturing process of a portion of the semiconductor device of the first embodiment according to the first example.

FIG. 14 illustrates an example of a state during the manufacturing process of a portion of the semiconductor device of the first embodiment according to the first example.

FIG. 15 illustrates an example of a state during the manufacturing process of a portion of the semiconductor device of the first embodiment according to the second example.

FIG. 16 illustrates an example of a cross-sectional structure of a portion of a semiconductor device according to a modification of the first embodiment.

### DETAILED DESCRIPTION

In general, according to one embodiment, a semiconductor device includes a first substrate, a first insulator, a first conductor, a second substrate, a first well region, a first impurity region, and a second well region. The first insulator is located in a first direction from the first substrate. The first conductor is in the first insulator. The second substrate is located more in the first direction than the first insulator. The first well region has a first conductivity type, is provided in the second substrate, and has a first impurity concentration. The first impurity region has the first conductivity type, is in contact with the first well region in the second substrate at a position located more in a second direction than the first well region, and has a second impurity concentration that is 4 times to 1×10⁸ times the first impurity concentration. The second well region has a second conductivity type and is in contact with the first impurity region in the second substrate at a position located more in the second direction than the first impurity region.

Embodiments will now be described with reference to the figures. In order to distinguish components having substantially the same function and configuration in an embodiment or over different embodiments from each other, an additional numeral or letter may be added to the end of each reference numeral or letter.

The figures are schematic, and the relation between the thickness and the area of a plane of a layer and the ratio of thicknesses of layers may differ from those in actuality. The figures may include components which differ in relations and/or ratios of dimensions in different figures.

The specification and the claims, when mentioning that a particular (first) component is “coupled” to another (second) component, intend to cover both the form of the first component directly coupled to the second component and the form of the first component coupled to the second component via one or more components which are always or selectively conductive.

Embodiments will be described using a three-dimensional orthogonal coordinate system. A direction of an x axis is referred to as an X direction. A direction opposite to the X direction is referred to as a −X direction. A direction of a y axis is referred to as a Y direction. A direction opposite to the Y direction is referred to as a −Y direction. A direction of a z axis is referred to as a Z direction, and up indicates the Z direction. A direction opposite to the Z direction is referred to as a −Z direction.

### 1. First Embodiment

### 1.1. Configuration (Structure)

The semiconductor device of the first embodiment is, for example, a memory device. A memory device 1 will be described as an example of a semiconductor device.

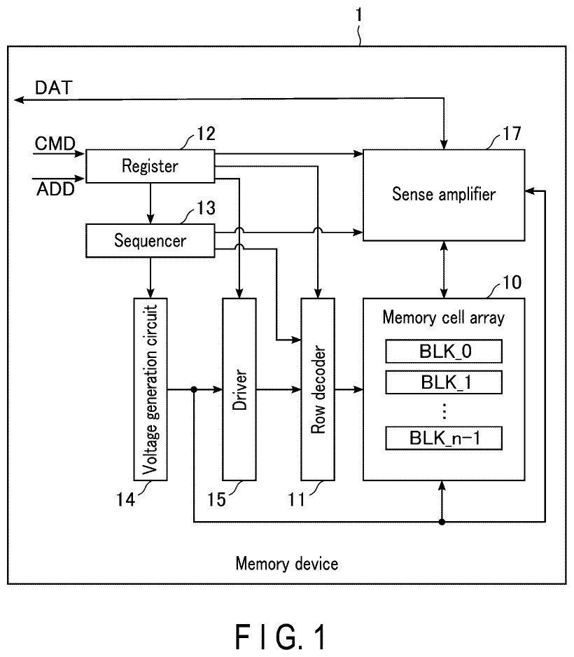

FIG. 1 illustrates an example of components of a memory device according to a first embodiment and how they are coupled. A memory device 1 is a device that stores data using memory cells. The memory device (semiconductor memory device) 1 is controlled by an external memory controller. The memory device 1 operates based on, for example, a command CMD and address information ADD received from the memory controller. The memory device 1 receives data DAT to be written, and outputs data stored in the memory device 1.

The memory device 1 includes components such as a memory cell array 10, a row decoder 11, a register 12, a sequencer 13, a voltage generation circuit 14, a driver 15, and a sense amplifier 17.

The memory cell array 10 is a set of arrayed memory cells. The memory cell array 10 includes a plurality of memory blocks (blocks) BLK. Each block BLK includes a plurality of memory cell transistors MT (not shown). An area where the memory cell array 10 is provided includes interconnects such as word lines WL (not shown) and bit lines BL (not shown).

The row decoder 11 is a circuit for selecting a block BLK. The row decoder 11 transfers a voltage supplied from the driver 15 to a single block BLK selected based on a block address received by the row decoder 11 from the register 12.

The register 12 is a circuit that holds the command CMD and the address information ADD received by the memory device 1. The command CMD instructs the sequencer 13 to perform various operations including data reading, data writing, and data erasing. The address information ADD designates an access target in the memory cell array 10.

The sequencer 13 is a circuit that controls the entire operation of the memory device 1. The sequencer 13 controls the row decoder 11, the driver 15, and the sense amplifier 17 based on the command CMD received from the sequencer 13 to perform various operations including data reading, data writing, and data erasing.

The voltage generation circuit 14 is a circuit that generates voltages of different magnitudes. The voltage generation circuit 14 receives a power-supply voltage from outside the memory device 1, and generates a plurality of voltages from the power-supply voltage. The voltage generation circuit 14 supplies the generated voltages to components such as the memory cell array 10, the driver 15, and the sense amplifier 17.

The driver 15 is a circuit that applies various voltages necessary for operating the memory device 1 to some of the components. The driver 15 receives multiple voltages from the voltage generation circuit 14, selects one or more of the voltages, and supplies the selected voltages to one or more row decoders 11.

The sense amplifier 17 is a circuit that outputs a signal based on data stored in the memory cell array 10. The sense amplifier 17 senses a state of each memory cell transistor MT, and generates read data based on the sensed state. The sense amplifier 17 applies a voltage based on write data to a bit line BL.

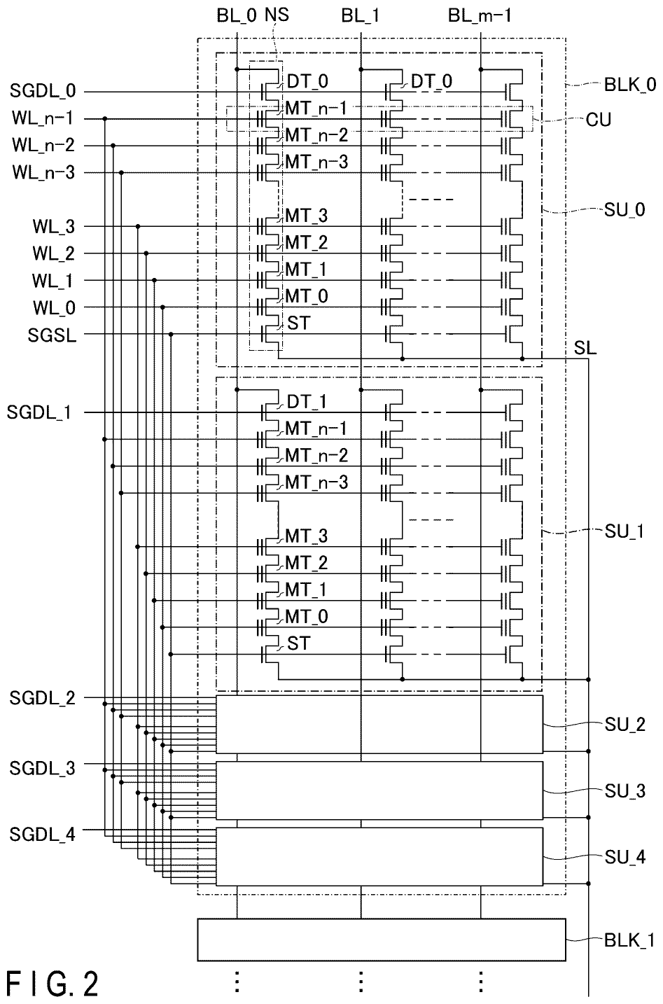

FIG. 2 illustrates components and coupling of the components of a single block of the semiconductor device of the first embodiment. A plurality of blocks BLK, for example, all blocks BLK, include the components and the coupling illustrated in FIG. 2.

A single block BLK includes a plurality of string units SU. FIG. 2 illustrates an example of five string units SU_0 to SU_4.

As illustrated in FIG. 2, each of m bit lines BL_0 to BL_m-1 is coupled, in each block BLK, to a single NAND string NS from each of string units SU_0 to SU_4, where m is a positive integer.

Each NAND string NS includes a single select gate transistor ST, n memory cell transistors MT, and a single select gate transistor DT (DT_0, DT_1, DT_2, DT_3, or DT_4), where n is a positive integer. The memory cell transistor MT is an element that functions as a memory cell and stores data in a nonvolatile manner. The memory cell transistor MT (MT_0 to MT_n-1) includes a control gate electrode or gate electrode (or, word line WL) and a charge accumulation film insulated from the surroundings, and stores data in a nonvolatile manner based on a charge in the charge accumulation film. Data is written to the memory cell transistor MT by injecting electrons into the charge accumulation film.

The select gate transistors ST, memory cell transistors MT_0 to MT_n-1, and select gate transistor DT are coupled in series in the named order between a source line SL and a single bit line BL.

A plurality of NAND strings NS respectively coupled to a plurality of different bit lines BL constitute a single string unit SU. In each string unit SU, the control gate electrodes of the memory cell transistors MT_0 to MT_n-1 are coupled to the word lines WL_0 to WL_n-1, respectively. A set of memory cell transistors MT which share a single word line WL in one string unit SU, is referred to as a “cell unit CU”.

The select gate transistors DT_0 to DT_4 belong to the string units SU_0 to SU_4, respectively. In FIG. 2, the select gate transistors DT_2, DT_3, and DT_4 are not illustrated. The gate of the select gate transistor DT_0 of each of the NAND strings NS of the string unit SU_0 is coupled to a select gate line SGDL_0. Similarly, the gates of the select gate transistors DT_1, DT_2, DT_3, and DT_4 of the respective NAND strings NS of the string units SU_1, SU_2, SU_3, and SU_4 are coupled to select gate lines SGDL_1, SGDL_2, SGDL_3, and SGDL_4.

The gate of the select gate transistor ST is coupled to a select gate line SGSL.

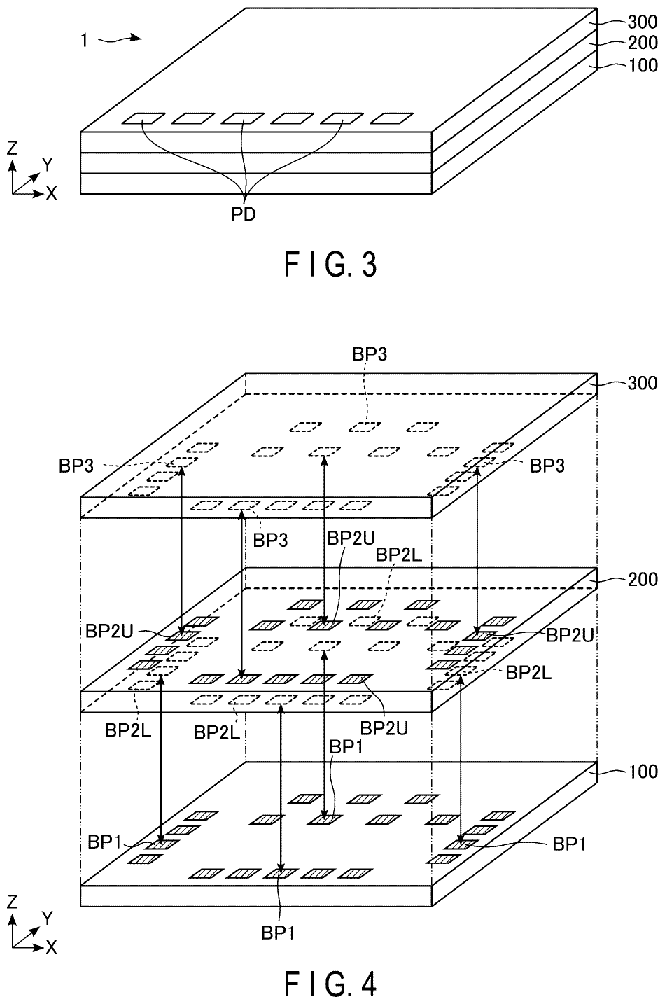

FIG. 3 illustrates an exterior of the semiconductor device of the first embodiment. As illustrated in FIG. 3, the memory device 1 includes a first structure 100, a second structure 200, and a third structure 300. The first structure 100, the second structure 200, and the third structure 300 spread along the xy plane and are arranged in the Z direction. The second structure 200 is located on a surface (or, upper surface) of the first structure 100 at a side of the Z direction. The third structure 300 is located on the upper surface of the second structure 200.

The first structure 100, the second structure 200, and the third structure 300 each include a plurality of semiconductors, a plurality of various conductors, and a plurality of insulators formed on a substrate using the substrate. The first structure 100, the second structure 200, and the third structure 300 each include a plurality of elements and interconnects implemented by semiconductors, conductors, and insulators. The first structure 100, the second structure 200, and the third structure 300 each include an electrical circuit including elements and interconnects. The elements and interconnects in the first structure 100, the elements and interconnects in the second structure 200, and the elements and interconnects in the third structure 300 are electrically coupled to each other.

The set of the first structure 100 and the second structure 200 includes the row decoder 11, the register 12, the sequencer 13, the voltage generation circuit 14, the driver 15, and the sense amplifier 17. The first structure 100 can include any one or ones of the row decoder 11, the register 12, the sequencer 13, the voltage generation circuit 14, the driver 15, and the sense amplifier 17. The second structure 200 can include any one or ones of the row decoder 11, the register 12, the sequencer 13, the voltage generation circuit 14, the driver 15, and the sense amplifier 17.

The third structure 300 includes the memory cell array 10 and the plurality of external connection terminals PD. The external connection terminals PD are exposed on an upper surface of the third structure 300.

FIG. 4 illustrates an example of the structure of some planes of the semiconductor device of the first embodiment. FIG. 4 illustrates an exploded view of the structure of FIG. 3.

As illustrated in FIG. 4, the first structure 100 includes a plurality of conductive joint terminals BP1. The joint terminals BP1 are exposed on a surface (or, upper surface of) the first structure 100 at a side of the Z direction. The joint terminals BP1 are coupled to elements inside the first structure 100.

The second structure 200 includes a plurality of conductive joint terminals BP2L and a plurality of conductive joint terminals BP2U. The joint terminals BP2L are exposed on a surface (or, lower surface) of the second structure 200 at a side of the-Z direction. The joint terminals BP2L are coupled to elements inside the second structure 200. The joint terminals BP2L have the same layout as the layout of the joint terminals BP1 of the first structure 100. The joint terminals BP2L are arranged such that when the first structure 100 and the second structure 200 are joined, each joint terminal BP2L makes contact with one of the joint terminals BP1 of the first structure 100 corresponding to the joint terminal BP2L. A specific joint terminal BP2L and the one of the joint terminals BP1 of the first structure 100 corresponding to the specific joint terminal BP2L are elements that function as the same node in the circuit.

The joint terminals BP2U are exposed on an upper surface of the second structure 200. The joint terminals BP2U are coupled to elements inside the second structure 200.

The third structure 300 includes a plurality of conductive joint terminals BP3. The joint terminals BP3 are exposed on a lower surface of the third structure 300. The joint terminals BP3 are coupled to elements inside the third structure 300. The joint terminals BP3 have the same layout as the layout of the joint terminals BP2U of the second structure 200. The joint terminals BP3 are arranged such that when the second structure 200 and the third structure 300 are joined, each joint terminal BP3 makes contact with one of the joint terminals BP2U of the second structure 200 corresponding to the joint terminal BP3. A specific joint terminal BP3 and the one of the joint terminals BP2U of the second structure 200 corresponding to the specific joint terminal BP3 are elements that function as the same node in the circuit.

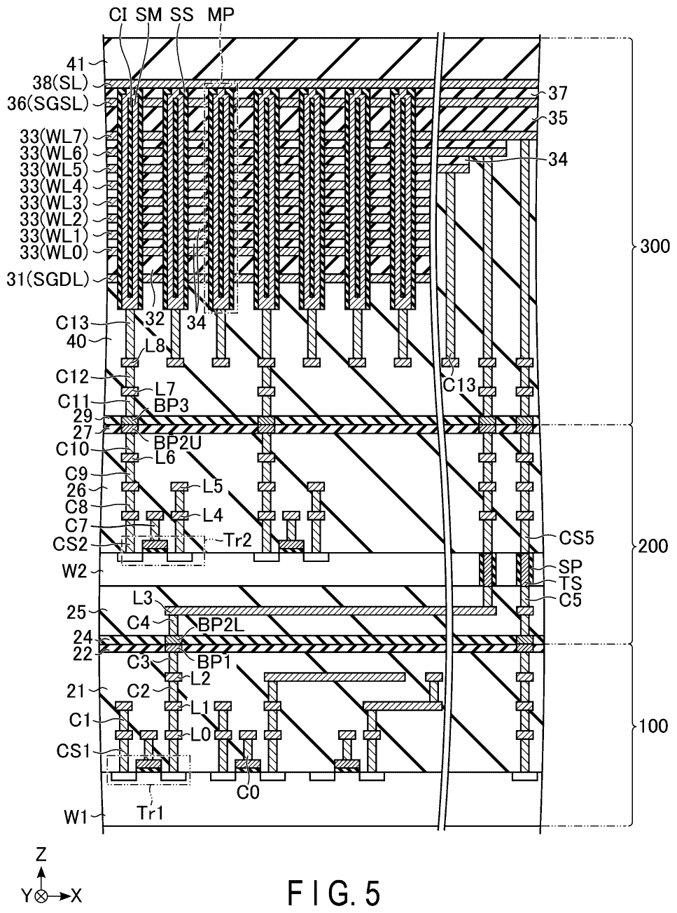

FIG. 5 illustrates an example of a partial sectional structure of the semiconductor device of the first embodiment. As illustrated in FIG. 5, the first structure 100 further includes a substrate W1, a transistor Tr1, contacts CS1, C0, C1, C2, and C3, conductors L0, L1, and L2, and insulators 21 and 22. In the following description, the conductor also includes a semiconductor which has conductivity by containing impurities. In one example, the substrate W1 contains silicon. In one example, the contacts CS1, C0, C1, C2, and C3, and the conductors L0, L1, and L2 contain copper (Cu), aluminum (Al), or tungsten (W). In one example, the insulators 21 and 22 contain silicon oxide.

The transistor Tr1 is located in a region above and near the upper surface of the substrate W1. The transistor Tr1 includes a gate insulator on an upper surface of the substrate W1, a gate electrode on an upper surface of the gate insulator, and a pair of source/drain regions sandwiching a region below the gate electrode.

Each contact C0 is in contact with an upper surface of the gate electrode of a single transistor Tr1 on a lower surface. Each contact CS1 is in contact with a single source/drain region on a lower surface.

Each conductor L0 is in contact with a single contact C0 or CS1 on a lower surface. Each contact C1 is in contact with an upper surface of a single conductor L0 on the lower surface.

Each conductor L1 is in contact with an upper surface of a single contact C1 on a lower surface. Each contact C2 is in contact with an upper surface of a single conductor L1 on a lower surface.

Each conductor L2 is in contact with an upper surface of a single contact C2 on a lower surface. Each contact C3 is in contact with an upper surface of a single conductor L2 on a lower surface.

A set of the transistor Tr1, the contacts CS1, C0, C1, C2, and C3, and the conductors L0, L1, and L2 implements a circuit included in the first structure 100. Therefore, the first structure 100 includes the transistor Tr1, the contacts CS1, C0, C1, C2, and C3, and the conductors L0, L1, and L2, which may have any shapes and arrangements to implement the circuit included in the first structure 100.

The insulator 21 ranges from the level of the upper surface of the substrate W1 to the level of an upper surface of the contact C3. The insulator 21 fills a region of the first structure 100 where components are not provided, that is, a region where the transistor Tr1, the contacts CS1, C0, C1, C2, and C3, and the conductors L0, L1, and L2 are not provided.

Each joint terminal BP1 is in contact with an upper surface of a single contact C3 on a lower surface. The insulator 22 fills a region in a layer in which the joint terminal BP1 is located where the joint terminal BP1 is not provided.

The second structure 200 further includes a substrate W2, a transistor Tr2, contacts CS2, CS5, C4, C5, C7, C8, C9, and C10, conductors L3, L4, L5, and L6, and insulators 24, 25, 26, and 27. In one example, the substrate W2 contains silicon. In one example, the contacts CS2, CS5, C4, C5, C7, C8, C9, and C10, and the conductors L3, L4, L5, and L6 contain copper, aluminum, or tungsten. In one example, the insulators 24, 25, 26, and 27 contain silicon oxide.

Each joint terminal BP2L is located in the lowermost layer of the second structure 200. The insulator 24 fills a region in a layer in which the joint terminal BP2L is located where the joint terminal BP2L is not provided.

Each contact C4 is in contact with an upper surface of a single joint terminal BP2L on a lower surface.

Each conductor L3 is in contact with an upper surface of a single contact C4 on a lower surface. Each contact C5 is in contact with an upper surface of a single conductor L3 on a lower surface.

The insulator 25 ranges from the level of the upper surface of the joint terminal BP2L and an upper surface of the insulator 24 to the level of an upper surface of the contact C5. The insulator 25 fills a region above the joint terminal BP2L and the insulator 24 where the contacts C4 and C5 and the conductor L3 are not provided.

The substrate W2 is located on an upper surface of the insulator 25. Vias TS penetrate the substrate W2 across an upper surface and a lower surface of the substrate W2. Each via TS is in contact with an upper surface of a single contact C5 on a lower surface. The insulator SP penetrates the substrate W2 across the upper surface and the lower surface of the substrate W2. Each insulator SP covers a side surface of a single via TS.

The transistor Tr2 is located in a region above and near the upper surface of the substrate W2. The transistor Tr2 includes a gate insulator on the upper surface of the substrate W2, a gate electrode on an upper surface of the gate insulator, and a pair of source/drain regions sandwiching a region below the gate electrode.

Each contact C7 is in contact with an upper surface of the gate electrode of a single transistor Tr2 on a lower surface. Each contact CS2 is in contact with a single source/drain region on a lower surface. Each contact CS5 is in contact with an upper surface of a single via TS on a lower surface.

Each conductor L4 is in contact with an upper surface of a single contact C7, CS2, or CS5 on a lower surface. Each contact C8 is in contact with an upper surface of a single conductor L4 on a lower surface.

Each conductor L5 is in contact with an upper surface of a single contact C8 on a lower surface. Each contact C9 is in contact with an upper surface of a single conductor L5 on a lower surface.

Each conductor L6 is in contact with an upper surface of a single contact C9 on a lower surface. Each contact C10 is in contact with an upper surface of a single conductor L6 on a lower surface.

A set of the transistor Tr2, the contacts CS2, CS5, C4, C5, C7, C8, C9, and C10, and the conductors L3, L4, L5, and L6 implements a circuit included in the second structure 200. Therefore, the second structure 200 includes the transistor Tr2, the contacts CS2, CS5, C4, C5, C7, C8, C9, and C10, and the conductors L3, L4, L5, and L6 which may have any shapes and arrangements to implement the circuit included in the second structure 200.

The insulator 26 ranges from the level of the upper surface of the substrate W2 to the level of an upper surface of the contact C10. The insulator 26 fills a region from the level of the upper surface of the substrate W2 to the level of the upper surface of the contact C10 where components are not provided, that is, a region where the transistor Tr2, the contacts CS2, C7, C8, C9, and C10, and the conductors L4, L5, and L6 are not provided.

Each joint terminal BP2U is in contact with an upper surface of a single contact C10 on a lower surface. The insulator 27 fills a region in a layer in which the joint terminal BP2U is located where the joint terminal BP2U is not provided.

The third structure 300 further includes contacts C11, C12, and C13, conductors L7, L8, 31, 33, 36, 38, insulators 29, 32, 34, 35, 37, 40, and 41, and a memory pillar MP.

Each joint terminal BP3 is located in the lowermost layer of the third structure 300. The insulator 29 fills a region in a layer in which the joint terminal BP3 is located where the joint terminal BP3 is not provided.

Each contact C11 is in contact with an upper surface of a single joint terminal BP3 on a lower surface.

Each conductor L7 is in contact with an upper surface of a single contact C11 on a lower surface. Each contact C12 is in contact with an upper surface of a single conductor L7 on a lower surface.

Each conductor L8 is in contact with an upper surface of a single contact C12 on a lower surface.

The conductor 31 is located above the conductor L8. The conductor 31 has a plate-like shape along the xy plane. The conductor 31 functions as at least a part of a select gate line SGDL. A lower surface of the conductor 31 is exposed at the edge and has a terrace.

The insulator 32 is located on an upper surface of the conductor 31. The insulator 32 has a plate-like shape along the xy plane.

The conductors 33 and the insulators 34 are stacked one-by-one alternately on an upper surface of the insulator 32. The conductors 33 and the insulators 34 have a plate-like shape along the xy plane. Each conductor 33 functions as at least a part of the word line WL. FIG. 5 illustrates an example where n, that is, the number of memory cell transistors MT, is 8. The conductors 33 function as at least a part of the word lines WL_0, WL_1, WL_2, WL_3, WL_4, WL_5, WL_6, and WL_7 in order from the bottom. A lower surface of each conductor 33 is exposed at the edge and has a terrace.

The insulator 35 is located on an upper surface of the uppermost conductor 33.

The conductor 36 is located on an upper surface of the insulator 35. The conductor 36 functions as at least a part of a select gate line SGSL.

The insulator 37 is located on an upper surface of the conductor 36. The conductor 38 is located on an upper surface of the insulator 37. A lower surface of the conductor 38 is exposed at the edge and has a terrace.

The memory pillars MP extend along the z axis and penetrate the set of the conductors 31, 33, and 36, and the insulators 32, 34, 35, and 37. Each memory pillar MP includes an insulator CI, a semiconductor SM, and a layer stack SS. The semiconductor SM covers a side surface of the insulator CI. The layer stack SS covers a side surface of the semiconductor SM. The layer stack SS is open at an upper end of the memory pillar MP. A part of the semiconductor SM is located in the opening and is in contact with the conductor 38 on an upper surface.

An upper part of the memory pillar MP may be located inside the conductor 38, the layer stack SS may be open in a portion facing the conductor 38, and a part of the semiconductor SM may be located inside the opening.

A part of each memory pillar MP that faces the conductor 31 functions as a single select gate transistor DT. A part of the memory pillar MP that faces the conductor 33 functions as a single memory cell transistor MT. A part of the memory pillar MP that faces the conductor 36 functions as a single select gate transistor ST. A lower surface of the semiconductor SM is exposed on a lower surface of each memory pillar MP. A lower surface of the semiconductor SM is exposed on a lower surface of a single memory pillar MP.

Each contact C13 is in contact with an upper surface of a single conductor L8 on a lower surface. Each of several contacts C13 is in contact with the lower surface of the semiconductor SM of a single memory pillar MP on an upper surface. Each of several contacts C13 is in contact with a lower surface of the terrace portion of one of the conductors 31, 33, and 36 on an upper surface.

The insulator 40 ranges from the level of an upper surface of the insulator 29 to the level of an upper surface of the conductor 38. The insulator 40 fills a region of the third structure 300 where components are not provided, that is, a region where the contacts C11, C12, and C13, the conductors L7, L8, 31, 33, 36, and 38, the insulators 40, 32, 34, 35, and 37, and the memory pillar MP are not provided.

The insulator 41 is located on an upper surface of each of the conductor 38 and the insulator 40.

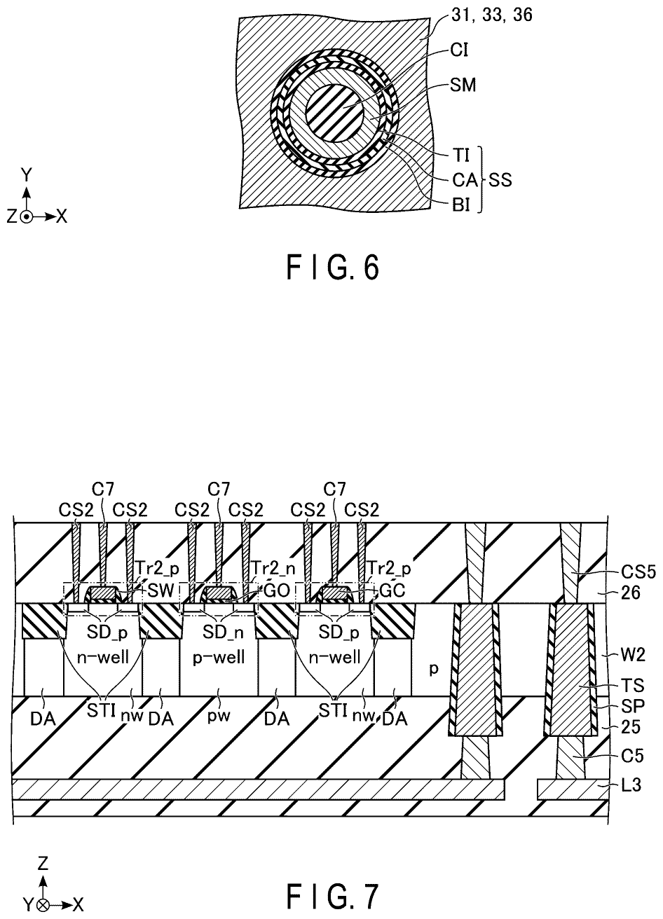

FIG. 6 illustrates an example of a cross-sectional structure of the memory pillar of the semiconductor device of the first embodiment along the xy plane. As illustrated in FIG. 6, in one example, the layer stack SS includes a tunnel insulator TI, a charge accumulation film CA, and a block insulator BI.

The tunnel insulator TI surrounds a side surface of the semiconductor SM. The charge accumulation film CA surrounds a side surface of the tunnel insulator TI. The block insulator BI surrounds a side surface of the charge accumulation film CA. The conductor 31, 33 or 36 surrounds a side surface of the block insulator BI.

The semiconductor SM functions as a channel (or, current path) for the memory cell transistor MT and the select gate transistors DT and ST. In one example, each of the tunnel insulator TI and the block insulator BI contains silicon oxide. The charge accumulation film CA accumulates charge. In one example, the charge accumulation film CA contains silicon nitride.

FIG. 7 illustrates a structure of a portion of the semiconductor device of the first embodiment. FIG. 7 illustrates details of the substrate W2 and its surrounding structure.

As illustrated in FIG. 7, the second structure 200 further includes a structure STI, an n-well region nw, a p-well region pw, and an impurity region DA. Although FIG. 7 illustrates only one p-well region pw, two or more p-well regions pw are provided in practice.

The substrate W2 contains p-type impurities. An example of the p-type impurities includes boron (B).

The structure STI separates elements, includes an insulator, and has a structure using shallow trench isolation (STI). The structure STI is located in a region including the upper surface of the substrate W2. The structure STI extends downward from the upper surface of the substrate W2. In one example, the structure STI contains silicon oxide.

The n-well region nw is located between two adjacent structures STI. The n-well region nw extends from the upper surface to the lower surface of the substrate W2. The n-well region nw contains n-type impurities. Examples of the n-type impurities include phosphorus (P) and arsenic (As).

The p-well region pw is located between two adjacent structures STI. The p-well region pw extends from the upper surface to the lower surface of the substrate W2. The p-well region pw contains p-type impurities. In one example, the p-well region pw contains p-type impurities in a region including the boundary with the insulator 25 at a concentration of 1×10¹⁴ [atoms/cm³] to 2×10¹⁶ [atoms/cm³]. In one example, the impurity concentration is an average concentration.

The transistors Tr2 include a p-type transistor Tr2_p and an n-type transistor Tr2_n.

The transistor Tr2_p is located between two adjacent structures STI. The transistor Tr2_p is located in the n-well region nw and above the n-well region nw. The transistor Tr2_p includes a gate insulator GO, a gate electrode GC, and a pair of source/drain regions SD_p. The gate insulator GO is located on the upper surface of substrate W2. In one example, the gate insulator GO contains silicon oxide. The gate electrode GC is located on the upper surface of the gate insulator GO. In one example, the gate electrode GC contains polysilicon that is conductive through doped impurities. The source/drain regions SD_p sandwich the portion that is below the gate electrode GC in the surface region of the semiconductor substrate W2. The source/drain region SD_p contains p-type impurities.

The transistor Tr2_n is located between two adjacent structures STI. The transistor Tr2_n is located in the p-well region pw and above the p-well region pw. The transistor Tr2_n includes a gate insulator GO, a gate electrode GC, and a pair of source/drain regions SD_n. The source/drain regions SD_n sandwich the portion that is below the gate electrode GC in the surface region of the semiconductor substrate W2. The source/drain regions SD_n contain n-type impurities.

Each impurity region DA is located below one structure STI in the substrate W2. The impurity region DA is in contact with the lower surface of the structure STI and reaches the lower surface of the substrate W2. The impurity region DA is in contact with two adjacent regions of the n-well region nw and the p-well region pw, and electrically isolates these adjacent regions. The impurity region DA contains p-type impurities. An example of the p-type impurities includes boron. The impurity region DA is formed by ion implantation or the like, independently of the p-well region pw. The impurity region DA has a higher impurity concentration than the p-well region pw and a higher p-type impurity concentration than the p-type impurity concentration which the impurity region DA would have at the location if the p-type impurities in the p-well region pw were to diffuse without forming of the impurity region DA. In one example, the impurity region DA contains p-type impurities at a concentration of 1×10¹⁶ [atoms/cm³] or more and 3×10¹⁸ [atoms/cm³] or less. In one example, the impurity region DA contains p-type impurities in a region including the boundary with the insulator 25 at a concentration of 8×10¹⁶ [atoms/cm³] or more and 1×10²² [atoms/cm³] or less. In one example, the p-type impurity concentration of the impurity region DA is 4 times or more and 1×10⁸ times or less than the p-type impurity concentration of the p-well region pw.

The contacts CS2, CS5 and C7 and the structure STI have a tapered shape. The components with a tapered shape have a larger area at the top end than at the bottom end. In one example, the components with a tapered shape have an area (an area along the xy plane) that decreases from the top end to the bottom end. That is, the contacts CS2, CS5 and C7 and the structure STI have a larger area at the Z direction end than at the −Z direction end.

The via TS, the insulator SP, and the contact C5 have an inverted tapered shape. The components with an inverted tapered shape have a smaller area at the top end than at the bottom end. In one example, the components with an inverted tapered shape have an area that increases from the top end to the bottom end. That is, the via TS, the insulator SP, and the contact C5 have a smaller area at the Z direction end than at the −Z direction end.

The p-well region pw, together with another p-well region (not shown), sandwiches an n-well region nw.

### 1.2. Manufacturing Method

The manufacturing process of the memory device 1 includes a process of manufacturing the first structure 100, the second structure 200, and the third structure 300 in independent steps, and a process of bonding the manufactured first structure 100, second structure 200, and third structure 300 to each other. A manufacturing method of the second structure 200 will be described below.

### 1.2.1. First Example of Manufacturing Method of Second Structure

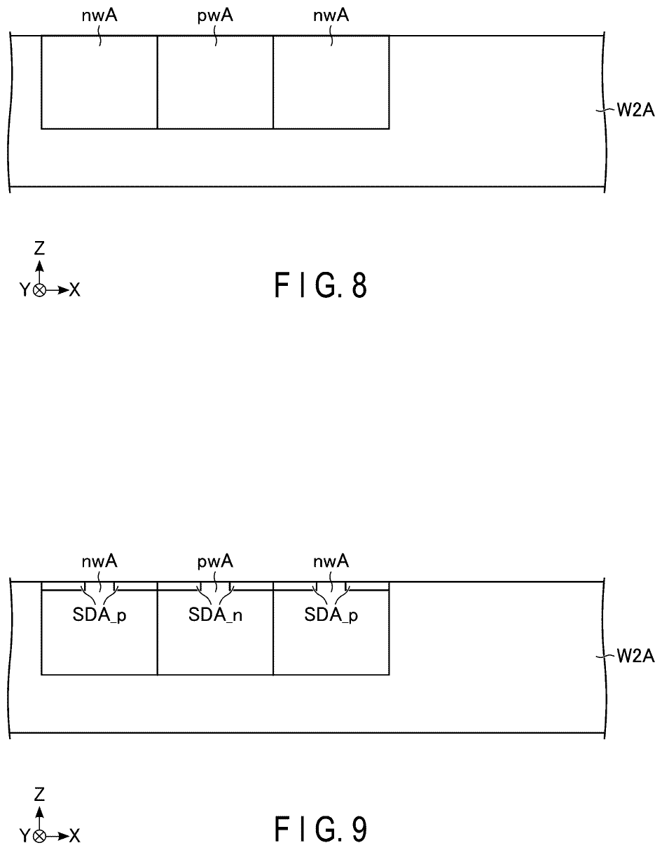

FIGS. 8 through 14 each illustrate an example of the second structure of the semiconductor device of the first embodiment during its manufacturing process according to the first example.

As illustrated in FIG. 8, an n-well region nwA and a p-well region pwA are formed in a substrate W2A. The substrate W2A is an element that will be processed as the substrate W2 in a later process. The n-well region nwA includes an n-well region nw and is located in the region where an impurity region DA is to be formed. The p-well region pwA includes a p-well region pw and is located in the region where the impurity region DA is to be formed.

Either the n-well region nwA or the p-well region pwA may be formed first. An example of a method for forming the n-well region nwA and the p-well region pwA includes ion implantation using a mask.

As illustrated in FIG. 9, source/drain regions SDA_n and SDA_p are formed in the substrate W2A. The source/drain region SDA_n includes a source/drain region SD_n and is located in the region where the impurity region DA is to be formed. The source/drain region SDA_p includes a source/drain region SD_p and is located in the region where the impurity region DA is to be formed.

Either the source/drain region SDA_n or the source/drain region SDA_p may be formed first. An example of a method for forming the source/drain regions SDA_n and SDA_p includes ion implantation using a mask.

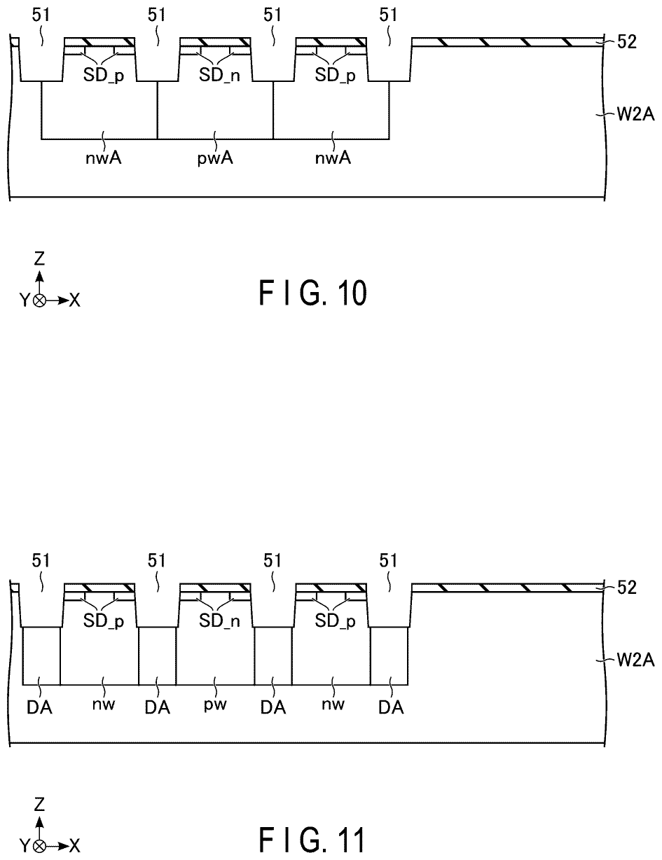

As illustrated in FIG. 10, a trench 51 is formed. The trench 51 occupies the region where a structure STI is to be formed. Examples of the method of formation include a combination of a photolithography process and anisotropic etching, and an example of anisotropic etching includes reactive ion etching (RIE). That is, a mask 52 is formed on the upper surface of the substrate W2A. The mask 52 has an opening above the region where the structure STI is to be formed, and exposes the upper surface of the substrate W2A at the opening. Then, a trench 51 is formed below the opening of the mask 52 by anisotropic etching of the mask 52. After the formation of the trench 51, the n-well region nwA becomes an n-well region nw, and the p-well region pwA becomes a p-well region pw. Also, after the formation of the trench 51, the source/drain region SDA_n becomes a source/drain region SD_n, and the source/drain region SDA_p becomes a source/drain region SD_p.

As illustrated in FIG. 11, an impurity region DA is formed. That is, by performing ion implantation using the mask 52, the impurity region DA is formed in the substrate W2A below the trench 51. The implanted ions include impurity elements contained in the impurity region DA.

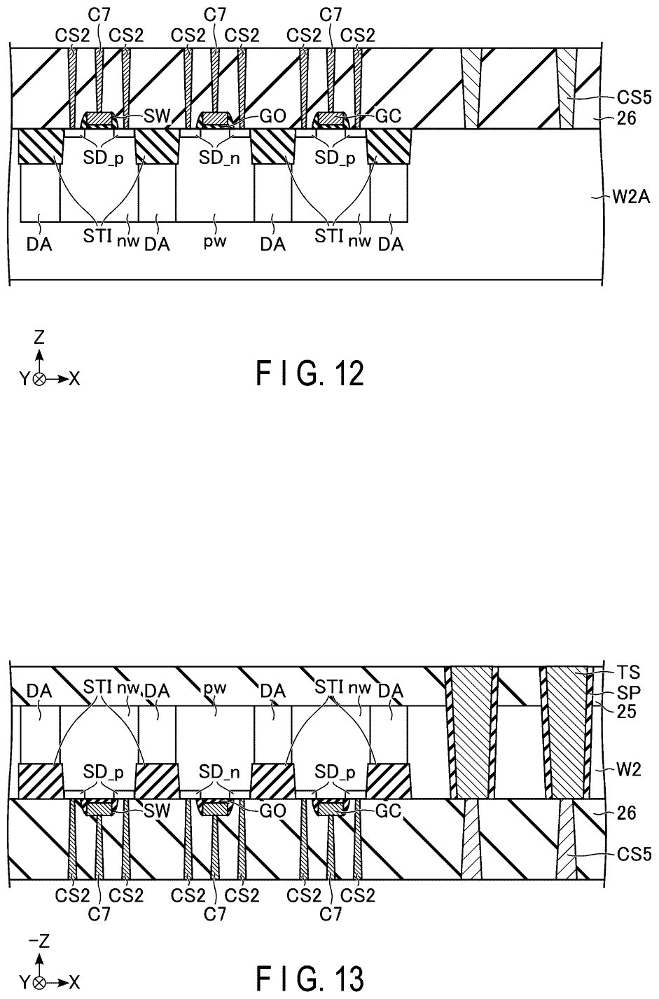

As illustrated in FIG. 12, a structure STI, a gate insulator GO, a gate electrode GC, a sidewall insulator SW, an insulator 26, and contacts CS2, CS5 and C7 are formed. That is, a material for the structure STI is first deposited in the trench 51. Examples of the deposition method includes chemical vapor deposition (CVD).

The gate insulator GO, the gate electrode GC, and the sidewall insulator SW are formed. Examples of the method for forming the gate insulator GO include thermal oxidation. Examples of the method for forming the gate electrode GC include CVD, as well as a combination of the photolithography process and anisotropic etching. Examples of the method for forming the sidewall insulator SW include CVD, as well as a combination of the photolithography process and anisotropic etching.

An insulator 26 is formed on the upper surface of the structure obtained through the steps performed up to this point. Examples of the formation method include CVD.

Contacts CS2, CS5, and CS7 are formed. Examples of the formation method include a combination of the photolithography process and anisotropic etching, and CVD.

Then, the contacts C8, C9 and C10 illustrated in FIG. 5, conductors L4, L5 and L6, an insulator 27, and a bonding terminal BP2U (not shown) are formed.

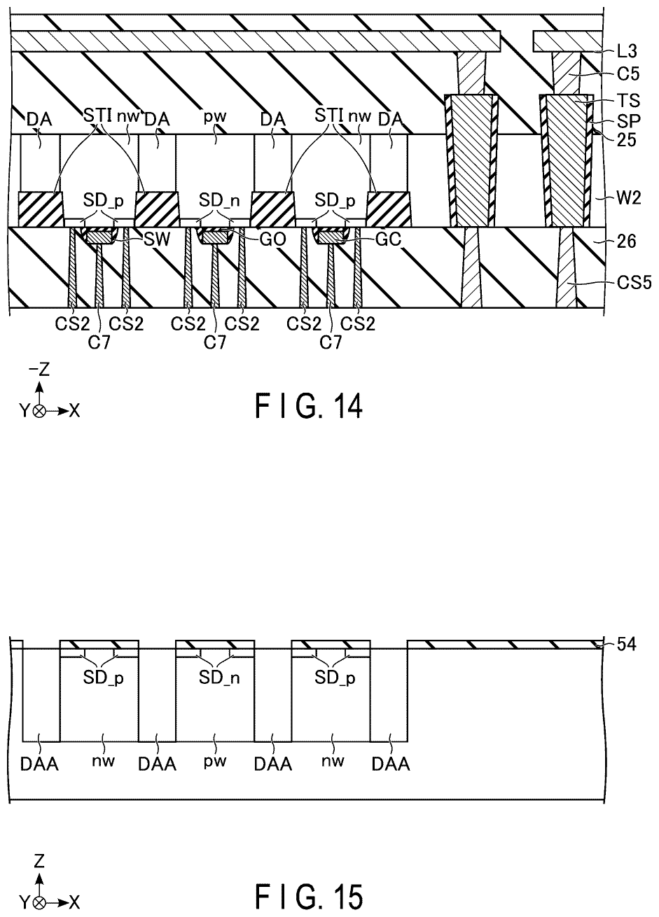

As illustrated in FIG. 13, the structure obtained through the steps performed up to this point is inverted with respect to the xy plane. In the descriptions given with reference to FIG. 13 and FIG. 14, “upper surface” refers to a surface on the side in the −Z direction.

The upper surface of the substrate W2A is polished by chemical mechanical polishing (CMP). As a result, the substrate W2A becomes thin, and the substrate W2 is formed thereby. CMP is performed until the impurity region DA is exposed.

A portion of the insulator 25 is formed on the upper surface of the substrate W2. Examples of the formation method include CVD.

A via TS and an insulator SP are formed. Examples of the formation method include a combination of the photolithography process and anisotropic etching, and CVD.

As illustrated in FIG. 14, the remaining portion of the insulator 25, the contact C5 and the conductor L3 are formed. Examples of the formation method include a combination of the photolithography process and anisotropic etching, and CVD.

Then, the contact C4 illustrated in FIG. 5, an insulator 24, and a bonding terminal BP1 are formed.

### 1.2.2. Second Example of Manufacturing Method of Second Structure

FIG. 15 illustrates an example of the second structure of the semiconductor device of the first embodiment during its manufacturing process according to the second example. The process described with reference to FIG. 15 follows the process described above with reference to FIG. 9.

As illustrated in FIG. 15, a mask 54 is formed on the upper surface of the structure obtained by the process described above with reference to FIG. 9. The mask 54 has an opening above the region where an impurity region DA is to be formed.

By performing ion implantation using the mask 54, an impurity region DAA is formed in the substrate W2A below the opening of the mask 54. The impurity region DAA extends from the upper surface of the substrate W2A and reaches the lower end of the region where the impurity region DA is to be formed.

As illustrated in FIG. 11, a trench 51 is formed. That is, the mask 54 is removed, a mask 52 is formed, and a trench 51 is formed below the opening of the mask 52, as in the process described above with reference to FIG. 10. The mask 52 may be the same as the mask 54. The subsequent steps are similar to those described in the first example.

### 1.3. Advantages (Advantageous Effects)

According to the first embodiment, a memory device in which leakage current is suppressed can be provided, as described below.

As a reference structure for comparison, a structure that does not include the impurity region DA of the first embodiment will be considered. In this structure, a p-well region pwA and an n-well region nwA, such as those illustrated in FIG. 10, are included in place of the p-well region pw and the n-well region nw of the first embodiment. Among the n-well region nwA, the p-well region pwA, and the n-well region nwA, two adjacent regions are contiguous. In the reference structure, when a positive high voltage is applied to the conductor L3, an inversion layer is formed in the p-well region pwA. That is, the electric field generated by the positive high voltage causes electrons to accumulate in that portion of the p-well region pwA which faces the conductor L3, thereby forming an n-type region. The n-type region electrically couples the n-well regions nw located on both sides. As a result, a leakage current flows between the n-well regions nwA through the n-type region.

Electrons are more likely to accumulate in a case where the distance between the conductor L3 and the p-well region pwA is short. The distance between the conductor L3 and the p-well region pwA depends on the thickness of the substrate W2 (particularly the distance between the bottom end of the p-well region pwA and the bottom end of the substrate W2) and the thickness of the insulator 25. The aspect ratio of the vias TS is preferably small to enable a high-density arrangement of the vias TS. For this purpose, it is desirable for the substrate W2 and the insulator 25 to be thin. As a result of thinning the substrate W2, the bottom end of the p-well region pw aligns with the bottom end of the substrate W2. Consequently, the distance between the conductor L3 and the p-well region pw is short.

The memory device 1 of the first embodiment includes an n-well region nw and a p-well region pw arranged side by side, and a p-type impurity region DA located between the n-well region nw and the p-well region pw. The impurity region DA has an impurity concentration higher than the impurity concentration of the p-well region pw. Thus, even if a positive high voltage is applied to the conductor L3, it is less likely for an n-type region to be formed in the portion of the impurity region DA facing the conductor L3 than in the portion of the p-well region pw facing the conductor L3, where an n-type region is formed. For this reason, even if an n-type region is formed in the p-well region pw by application of a positive high voltage to the conductor L3, the impurity region DA prevents two n-well regions nw from being electrically coupled through the n-type region in the p-well region pw. Consequently, a leakage current between the n-well regions nw is suppressed.

### 1.4. Modifications

The above description relates to an example in which the impurity region DA contains p-type impurities at a concentration higher than the concentration of the p-type impurities in the p-well region pw. The impurity region DA may contain n-type impurities at a concentration higher than the concentration of the n-type impurities in the n-well region nw. By a mechanism similar to that through which leakage current occurs due to the formation of an n-type region in the p-well region pw, leakage current may also occur due to the formation of a p-type region in the n-well region nw. That is, a p-type region is formed in the n-well region nw by application of a negative high voltage to the conductor L3, and the p-type region electrically couples the p-well regions pw located on both sides.

Even in this case, the leakage current is suppressed in the first embodiment. That is, because the impurity region DA contains n-type impurities at a concentration higher than that of the n-type impurities in the n-well region nw, it is unlikely for a p-type region to be formed in the portion of the impurity region DA facing the conductor L3, even if a negative high voltage is applied to the conductor L3. Therefore, even if a p-type region is formed in the n-well region nw by application of a negative high voltage to the conductor L3, the impurity region DA prevents the two p-well regions pw from being electrically coupled through the p-type region in the n-well region nw.

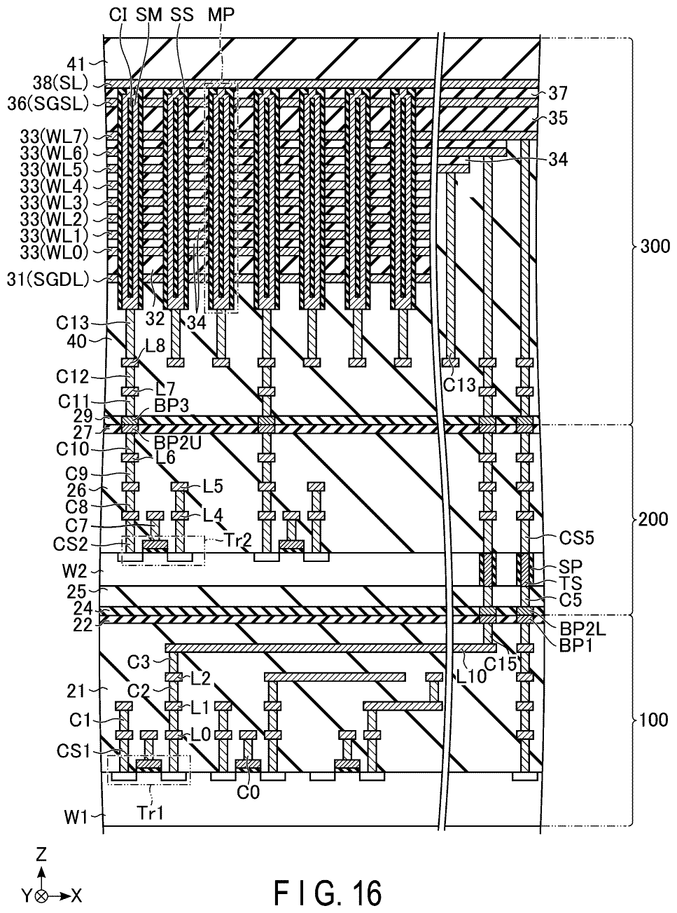

The conductor L3, which faces the p-well region pw and can generate an n-type region in the p-well region pw by application of a positive high voltage, may be located in the first structure 100. FIG. 16 illustrates such an example, and illustrates an example of the cross-sectional structure of a portion of a memory device according to a modification of the first embodiment. FIG. 16 illustrates the same region as FIG. 5.

As illustrated in FIG. 16, the second structure 200 does not include a conductor L3 or a contact C4. On the other hand, the third structure 300 further includes a conductor L10 and a contact C15.

The contact C5 is in contact with an upper surface of a junction terminal BP2L at a lower surface. Each contact C3 is in contact with the lower surface of a single conductor L10 at an upper surface. Each contact C15 is in contact with an upper surface of a single conductor L10 at a lower surface. Each contact C15 is in contact with a lower surface of a single junction terminal BP1 at an upper surface. Like the conductor L3, the conductor L10 can receive a positive high voltage or a negative high voltage.

Even with the structure of the modification, an n-type region can be formed in the p-well region pw, and a p-type region can be formed in the n-well region nw, if the thickness of the insulator 25 and the thickness of the portion of the insulator 21 located above the upper surface of the conductor L10 are small. By providing the impurity region DA, leakage current due to the formed n-type region or p-type region is suppressed.

The descriptions so far are based on an example in which the semiconductor device of the first embodiment is a memory device. The first embodiment can be applied to a structure in which the first structure 100 and the second structure 200 are bonded to each other and which includes the transistor Tr2 and the conductor L3 (or L10). An example of another type of such a semiconductor device includes an image sensor and integrated circuits (ICs). In this case, the third structure 300 is not provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first substrate;
a first insulator located in a first direction from the first substrate;
a first conductor in the first insulator;
a second substrate located more in the first direction than the first insulator;
a first well region having a first conductivity type, provided in the second substrate, and having a first impurity concentration;
a first impurity region having the first conductivity type, being in contact with the first well region in the second substrate at a position located more in a second direction than the first well region, and having a second impurity concentration that is 4 times to 1×10⁸ times the first impurity concentration; and
a second well region having a second conductivity type and being in contact with the first impurity region in the second substrate at a position located more in the second direction than the first impurity region.

2. The semiconductor device according to claim 1, wherein the first well region, the second well region, and the first impurity region are in contact with the first insulator.

3. The semiconductor device according to claim 1, wherein the first conductor and the first well region are aligned in the first direction.

4. The semiconductor device according to claim 1, further comprising:
a first transistor including a source/drain region located in the first well region and a gate electrode located more in the first direction than the first well region.

5. The semiconductor device according to claim 1, further comprising:
a second conductor penetrating the second substrate in the first direction.

6. The semiconductor device according to claim 5, wherein the second conductor is located more in the second direction than the second well region and is electrically coupled to the first conductor.

7. The semiconductor device according to claim 1, wherein the first well region has the first impurity concentration at an end on a side in the first direction, and
the first impurity region has the second impurity concentration at an end on a side in the first direction.

8. The semiconductor device according to claim 1, wherein
the first conductivity type is p-type,
the first well region and the first impurity region contain boron (B),
the second conductivity type is n-type, and
the second well region contains phosphorus (P) or arsenic (As).

9. The semiconductor device according to claim 1, wherein
the first conductivity type is n-type,
the first well region and the first impurity region contain phosphorus (P) or arsenic (As),
the second conductivity type is p-type, and
the second well region contains boron (B).

10. The semiconductor device according to claim 1, further comprising:
a second impurity region having the first conductivity type, being in contact with the first well region in the second substrate in a third direction from the first well region, and having the second impurity concentration, the third direction being opposite to the second direction; and
a third well region having the second conductivity type, being in contact with the second impurity region in the second substrate at a position located more in the third direction than the second impurity region.

11. The semiconductor device according to claim 10, wherein the first well region, the second well region, the third well region, and the first impurity region are in contact with the first insulator.

12. The semiconductor device according to claim 10, wherein the first conductor and the first well region are aligned in the first direction.

13. The semiconductor device according to claim 10, further comprising:
a first transistor including a source/drain region located in the first well region and a gate electrode located more in the first direction than the first well region.

14. The semiconductor device according to claim 10, further comprising:
a second conductor penetrating the second substrate in the first direction.

15. The semiconductor device according to claim 14, wherein the second conductor is located more in the second direction than the second well region and is electrically coupled to the first conductor.

16. The semiconductor device according to claim 10, wherein the first well region has the first impurity concentration at an end on a side in the first direction, and
each of the first impurity region and the second impurity region has the second impurity concentration at an end on a side in the first direction.

17. The semiconductor device according to claim 10, wherein
the first conductivity type is p-type,
the first well region and the first impurity region contain boron (B),
the second conductivity type is n-type, and
the second well region and the third well region contain phosphorus (P) or arsenic (As).

18. The semiconductor device according to claim 10, wherein
the first conductivity type is n-type,
the first well region and the first impurity region contain phosphorus (P) or arsenic (As),
the second conductivity type is p-type, and
the second well region and the third well region contain boron (B).

19. The semiconductor device according to claim 1, wherein the first insulator includes a second insulator and a third insulator,
the semiconductor device further comprises a third conductor in the second insulator and a fourth conductor in the third insulator,
the third conductor is in contact with the fourth conductor, and
the first conductor is located in the third insulator.

20. The semiconductor device according to claim 1, wherein the first insulator includes a second insulator and a third insulator,
the semiconductor device further comprises a third conductor in the second insulator and a fourth conductor in the third insulator,
the third conductor is in contact with the fourth conductor, and
the first conductor is located in the second insulator.
